(19) United States
(12) Patent Application Publication
(10) Pub. No.: US 2026/0051341 A1
(43) Pub. Date: Feb. 19, 2026

(54) SEMICONDUCTOR MEMORY DEVICE

(71) Applicant: Samsung Electronics Co., Ltd., Suwon-si (KR)

(72) Inventors: Jiseong Kim, Suwon-si (KR); Sang-Yun Kim, Suwon-si (KR); Younghun Seo, Suwon-si (KR)

(21) Appl. No.: 19/298,446

(22) Filed: Aug. 13, 2025

(30) Foreign Application Priority Data
Aug. 14, 2024 (KR) 10-2024-0109242

(51) Int. Cl. G11C 5/06; G11C 11/4091; G11C 11/4097; H10B 12/00

(52) U.S. Cl. CPC G11C 5/063; G11C 11/4091; G11C 11/4097; H10B 12/315; H10B 12/482; H10B 12/485

(57) ABSTRACT

A semiconductor memory device may include vertical semiconductor patterns extending in a first direction, a plurality of bit lines on lower surfaces of the vertical semiconductor patterns, each of the bit lines extending in a second direction that is perpendicular to the first direction, and a plurality of first gate structures on first side surfaces of the vertical semiconductor patterns, each of the first gate structures extending in a third direction that is perpendicular to the first direction and intersects the second direction. The bit lines may include odd-numbered bit lines and even-numbered bit lines that are alternately arranged with one another along the third direction. First ones of the vertical semiconductor patterns that are electrically connected to the even-numbered bit lines may be laterally offset from second ones of the vertical semiconductor patterns that are electrically connected to the odd-numbered bit lines.

### CROSS-REFERENCE TO RELATED APPLICATIONS

This application claims priority under 35 U.S.C. § 119 to Korean Patent Application No. 10-2024-0109242 filed on Aug. 14, 2024, in the Korean Intellectual Property Office, the disclosure of which is incorporated by reference herein in its entirety.

### BACKGROUND OF THE INVENTION

Embodiments of the present disclosure described herein relate to a semiconductor memory device.

A semiconductor device is a core component that may be used to control or amplify an electrical signal in an electronic device, and various types of semiconductor devices may be manufactured. As a design rule of the semiconductor device is decreased, technology of manufacturing the semiconductor device is developing in a direction of improving integration, improving an operation speed, and improving a yield rate. Accordingly, a transistor having a vertical channel has been proposed to increase the degree of integration, reduce resistance, and increase current driving capabilities of the transistor.

### SUMMARY OF THE INVENTION

Embodiments of the present disclosure provide a semiconductor memory device having improved electrical characteristics and improved reliability.

According to some embodiments, a semiconductor memory device may include vertical semiconductor patterns extending in a first direction, a plurality of bit lines electrically connected to lower surfaces of the vertical semiconductor patterns, each of the bit lines extending in a second direction that is perpendicular to the first direction, and a plurality of first gate structures on first side surfaces of the vertical semiconductor patterns, each of the first gate structures extending in a third direction that is perpendicular to the first direction and intersects the second direction, wherein the bit lines include odd-numbered bit lines and even-numbered bit lines that are alternately arranged with one another along the third direction, and wherein first ones of the vertical semiconductor patterns that are electrically connected to the even-numbered bit lines are laterally offset from second ones of the vertical semiconductor patterns that are electrically connected to the odd-numbered bit lines.

According to some embodiments, a semiconductor memory device may include vertical semiconductor patterns extending in a first direction, a plurality of bit lines on lower surfaces of the vertical semiconductor patterns, each of the bit lines extending in a second direction that is perpendicular to the first direction, and a plurality of first gate structures on first side surfaces of the vertical semiconductor patterns, each of the first gate structures extending in a third direction that is perpendicular to the first direction and intersects the second direction, wherein the bit lines include odd-numbered bit lines and even-numbered bit lines that are alternately arranged with one another along the third direction, wherein the first gate structures include odd-numbered first gate structures and even-numbered first gate structures that are alternately arranged with one another along the second direction, wherein first ones of the vertical semiconductor patterns that are adjacent to the odd-numbered first gate structures are electrically connected to the odd-numbered bit lines, and wherein second ones of the vertical semiconductor patterns that are adjacent to the even-numbered first gate structures are electrically connected to the even-numbered bit lines.

According to some embodiments, a semiconductor memory device may include vertical semiconductor patterns extending in a first direction, a plurality of bit lines on lower surfaces of the vertical semiconductor patterns, each of the bit lines extending in a second direction that is perpendicular to the first direction, and a plurality of first gate structures on first side surfaces of the vertical semiconductor patterns, each of the first gate structures extending in a third direction that is perpendicular to the first direction and intersects the second direction, wherein the bit lines include odd-numbered bit lines and even-numbered bit lines that are alternately arranged with one another along the third direction, wherein the first gate structures include N first gate structures that are sequentially arranged along the second direction, with N being a natural number, wherein first ones of the vertical semiconductor patterns that are adjacent to (4N-3)^{th} and (4N-2)^{th} ones of the first gate structures are electrically connected to the odd-numbered bit lines, and wherein second ones of the vertical semiconductor patterns that are adjacent to (4N-1)^{th} and 4N^{th} ones of the first gate structures are electrically connected to the even-numbered bit lines.

### BRIEF DESCRIPTION OF THE FIGURES

The above and other objects and features of the present disclosure will become more apparent by describing in detail example embodiments thereof with reference to the accompanying drawings.

FIG. 1 is a rear view illustrating a semiconductor memory device according to some embodiments of the present disclosure.

FIG. 2 is a cross-sectional view taken along line A-A′ of FIG. 1.

FIG. 3 is a cross-sectional view taken along line B-B′ of FIG. 1.

FIG. 4 is a rear view illustrating the semiconductor memory device according to some embodiments of the present disclosure.

FIG. 5 is a rear view illustrating the semiconductor memory device according to some embodiments of the present disclosure.

FIG. 6 is a cross-sectional view taken along line A-A′ of FIG. 1 according to some embodiments of the present disclosure.

FIG. 7 is a cross-sectional view illustrating the semiconductor memory device according to some embodiments of the present disclosure.

FIG. 8 is a rear view illustrating the semiconductor memory device according to some embodiments of the present disclosure.

FIG. 9 is a rear view illustrating the semiconductor memory device according to some embodiments of the present disclosure.

FIGS. 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 18A, 18B, 19A, 19B, 20A, 20B, 21A, 21B, 22A, and 22B are cross-sectional views and rear views illustrating a method of manufacturing a semiconductor memory device according to some embodiments of the present disclosure.

### DETAILED DESCRIPTION

Hereinafter, example embodiments of the present disclosure will be described in more detail with reference to the accompanying drawings.

A semiconductor memory device according to some embodiments of the present disclosure may be a storage device based on a semiconductor element. For example, the semiconductor memory device may be a volatile memory such as a dynamic random access memory (DRAM), a synchronous DRAM (SDRAM), a double data rate (DDR) SDRAM, a low power double data rate (LPDDR) SDRAM, a graphics double data rate (GDDR) SDRAM, a DDR2 SDRAM, a DDR3 SDRAM, a DDR4 SDRAM, or a thyristor RAM (TRAM), or a nonvolatile memory such as a phase change random access memory (PRAM), a magnetic random access memory (MRAM), or a resistive random access memory (RRAM).

The semiconductor memory device according to some embodiments of the present disclosure may include memory cells including vertical channel transistors (VCTs). The VCT may refer to a transistor in which a semiconductor pattern extends in a direction perpendicular to an upper surface of a semiconductor substrate.

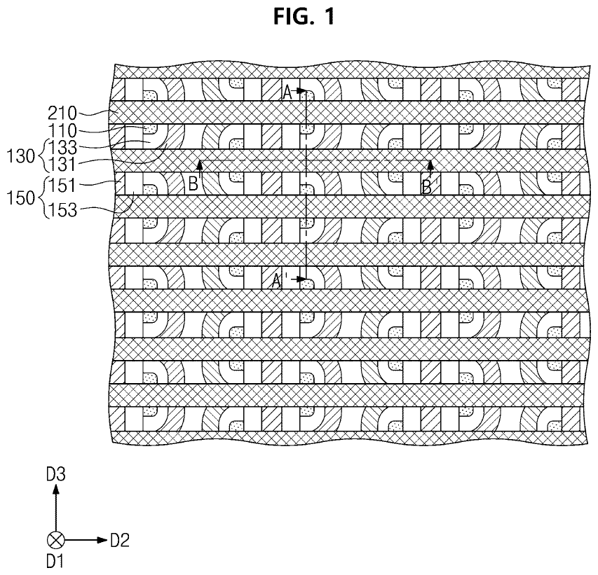

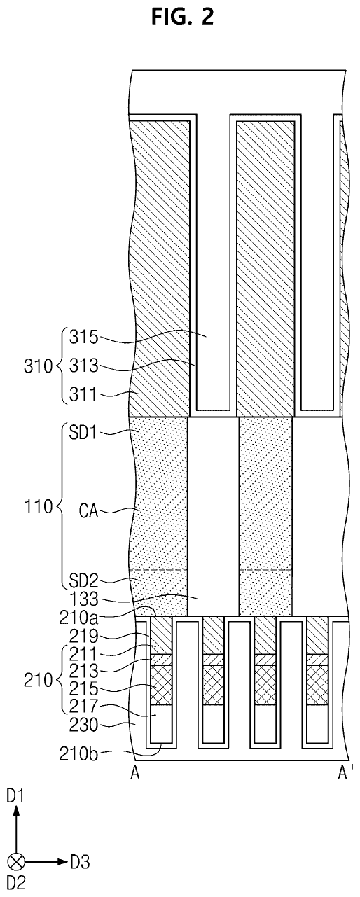

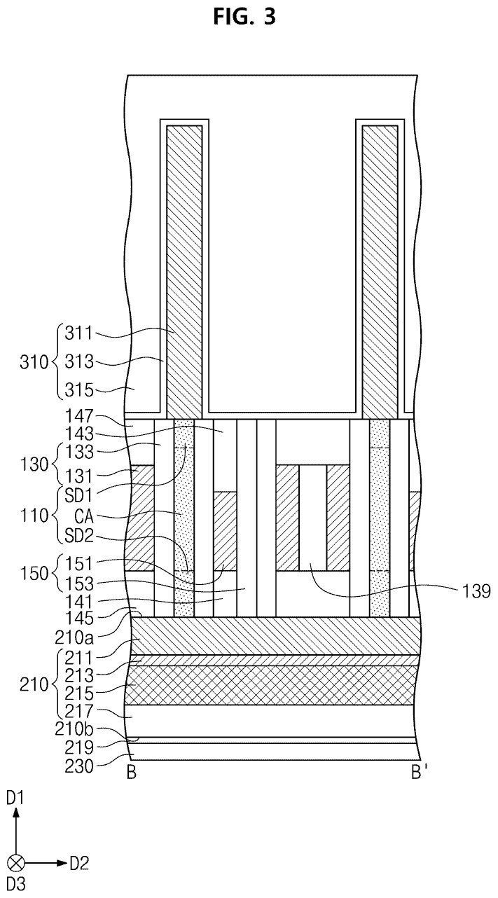

FIG. 1 is a rear view illustrating the semiconductor memory device according to some embodiments of the present disclosure. FIG. 2 is a cross-sectional view taken along line A-A′ of FIG. 1. FIG. 3 is a cross-sectional view taken along line B-B′ of FIG. 1.

Referring to FIGS. 1 to 3, the semiconductor memory device according to some embodiments of the present disclosure may include a vertical semiconductor pattern 110, a bit line 210, a first gate structure 130, a second gate structure 150, and a capacitor 310.

The vertical semiconductor pattern 110 may function as the VCT of the semiconductor memory device according to some embodiments of the present disclosure. The vertical semiconductor pattern 110 may be provided on a first surface 210a of the bit line 210 and may extend in a first direction D1. That is, the vertical semiconductor pattern 110 may be perpendicular to the bit line 210 (i.e., may extend perpendicular to the bit line 210). In some embodiments, the semiconductor memory device may include a plurality of vertical semiconductor patterns 110.

The vertical semiconductor pattern 110 may include a first source/drain area SD1, a second source/drain area SD2, and a channel area CA. The first source/drain area SD1 may be formed at an upper end of the vertical semiconductor pattern 110, and the second source/drain area SD2 may be formed at a lower end of the vertical semiconductor pattern 110. Here, the upper end may be an end of the vertical semiconductor pattern 110 in the first direction D1, and the lower end may be an end of the vertical semiconductor pattern 110 in a direction opposite to the first direction D1. The first source/drain area SD1 may be connected to the capacitor 310, and the second source/drain area SD2 may be connected to the bit line 210. The first source/drain area SD1 and the second source/drain area SD2 may function as sources or drains and supply or discharge carriers that carry a current. Here, the carrier may be an electron or a hole. The channel area CA may function as a passage through which the carrier moves. For example, the first source/drain area SD1 may function as a source, the second source/drain area SD2 may function as a drain, and the channel area CA may function as a passage (i.e., a channel) through which the carrier moves between the source and the drain. The first source/drain area SD1 and the second source/drain area SD2 may be areas doped with impurities having a conductivity type different from that of the channel area CA. For example, when the channel area CA includes first conductivity type impurities, the first source/drain area SD1 and the second source/drain area SD2 may be areas doped with second conductivity type impurities opposite thereto. For example, the first conductivity type impurities may be p-type impurities such as boron (B) that is a group 3 element, and the second conductivity type impurities may be n-type impurities such as phosphorus (P) and/or arsenic (As) that are group 5 elements. As used herein, the first source/drain area SD1 may also be referred to as a first source/drain region SD1, the second source/drain area SD2 may also be referred to as a second source/drain region SD2, and the channel area CA may also be referred to as a channel region CA.

The vertical semiconductor pattern 110 may include, for example, a semiconductor material such as silicon (Si), germanium (Ge), or silicon-germanium (Si—Ge). The vertical semiconductor pattern 110 may include an oxide semiconductor material. The oxide semiconductor material may be, for example, at least one of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbxGa_{y}Zn_{z}O, InₓGa_{y}O, and/or an indium gallium zinc oxide (IGZO). The vertical semiconductor pattern 110 may include a single layer or a plurality of layers made of the oxide semiconductor material. The vertical semiconductor pattern 110 may include an amorphous, crystalline, or polycrystalline oxide semiconductor material. In some embodiments, the vertical semiconductor pattern 110 may have a band gap energy greater than that of silicon. In some embodiments, the vertical semiconductor pattern 110 may include a two-dimensional semiconductor material. The two-dimensional semiconductor material may include, for example, graphene, MoS₂, WS₂, MoSe₂, WSe₂, or a combination thereof.

The bit line 210 may be provided on lower surfaces of the vertical semiconductor patterns 110. The bit line 210 may have a first surface 210a to which the vertical semiconductor patterns 110 are connected and a second surface 210b facing the same. In other words, the second surface 210b of the bit line 210 may be opposite to the first surface 210a of the bit line 210 (e.g., in the first direction D1). The bit line 210 may extend in a second direction D2 perpendicular to the first direction D1. In some embodiments, the semiconductor memory device may include a plurality of bit lines 210, and the bit lines 210 may be arranged in a third direction D3 perpendicular to the first direction D1 and intersecting the second direction D2. The bit lines 210 may extend in parallel to the second direction D2, and may be spaced apart from each other at regular intervals in the third direction D3. When the term “intersect” is used in this specification in connection with directional term(s), it is intended that “intersect” can include a range of angles, including, but not limited to, “perpendicular”.

Each of the bit lines 210 may include a buried conductive pattern 211, a contact pattern 213, a metal pattern 215, and a hardmask pattern 217, which are sequentially stacked in the direction opposite to the first direction D1. The buried conductive pattern 211 may include polysilicon doped with impurities. The contact pattern 213 may include at least one of, for example, tantalum (Ta), a tantalum nitride (TaN), titanium (Ti), a titanium nitride (TiN), a titanium silicon nitride (TiSiN), ruthenium (Ru), cobalt (Co), nickel (Ni), nickel boron (NiB), tungsten (W), a tungsten nitride (WN), a tungsten carbide (WC), zirconium (Zr), a zirconium nitride (ZrN), vanadium (V), a vanadium nitride (VN), niobium (Nb), a niobium nitride (NbN), platinum (Pt), iridium (Ir), rhodium (Rh), or a two-dimensional (2D) material. The metal pattern 215 may include at least one of a metal material (e.g., Al, Cu, Ti, Ta, Ru, W, Mo, Pt, Ni, and/or Co), a conductive metal nitride (e.g., TiN, TaN, WN, NbN, TiAlN, TiSiN, TaSiN, and/or RuTiN), a conductive metal silicide, or a conductive metal oxide (e.g., PtO, RuO₂, IrO₂, SRO(SrRuO₃), BSRO(Ba, Sr)RuO₃, CRO(CaRuO₃), and/or LSCo). The hardmask pattern 217 may include an insulating material such as a silicon nitride or a silicon oxynitride.

In some embodiments, the vertical semiconductor patterns 110 connected to the even-numbered bit lines 210 between the odd-numbered bit lines 210 adjacent to each other may be laterally offset from the vertical semiconductor patterns 110 connected to the odd-numbered bit lines 210 adjacent to each other. That is, when viewed on a plane (e.g., a rear view), the vertical semiconductor patterns 110 may be spaced apart from each other in the second direction D2 and the third direction D3. Here, a spacing distance between the vertical semiconductor patterns 110 may be constant.

For example, the bit lines 210 may include odd-numbered bit lines 210 and even-numbered bit lines 210 that are alternately arranged with one another along the third direction D3. That is, in the third direction D3, the bit lines 210 may alternate between an odd-numbered bit line 210 and an even-numbered bit line 210, with each odd-numbered bit line 210 being adjacent to an even-numbered bit line 210, and each even-numbered bit line 210 being adjacent to an odd-numbered bit line 210. In some embodiments, first ones of the vertical semiconductor patterns 110 that are connected to the even-numbered bit lines 210 may be laterally offset from second ones of the vertical semiconductor patterns 110 that are connected to the odd-numbered bit lines 210 (e.g., see FIG. 1). For example, first ones of the vertical semiconductor patterns 110 that are connected to the even-numbered bit lines 210 may not be aligned along the third direction D3 with second ones of the vertical semiconductor patterns 110 that are connected to the odd-numbered bit lines 210. For example, first ones of the vertical semiconductor patterns 110 that are connected to the even-numbered bit lines 210 may be shifted in the second direction D2 relative to second ones of the vertical semiconductor patterns 110 that are connected to the odd-numbered bit lines 210. In other words, a first one of the bit lines 210 may be adjacent to a second one of the bit lines 210 in the third direction D3, and a first one of the vertical semiconductor patterns 110 that is connected to the first one of the bit lines 210 may not be aligned along the third direction D3 with (and may be shifted in the second direction D2 relative to) a second one of the vertical semiconductor patterns 110 that is connected to the second one of the bit lines 210.

In some embodiments, an insulating pattern 219 may be provided on the first surfaces 210a of the bit lines 210, the lower surfaces of first gate insulating patterns 133, and the lower surfaces of the vertical semiconductor patterns 110. The insulating pattern 219 may be a film in which an insulating material is conformally formed on the first surfaces 210a of the bit lines 210, the lower surfaces of the first gate insulating patterns 133, and the lower surfaces of the vertical semiconductor patterns 110. In some embodiments, the first surfaces 210a of the bit lines 210 and the insulating pattern 219 may be arranged on the same plane (i.e., may be coplanar). The insulating pattern 219 may include at least one of, for example, a silicon oxide, a silicon nitride, a silicon oxynitride, or a low dielectric constant insulating material.

The first gate structure 130 may be on (e.g., may cover and/or overlap) first side surfaces of the vertical semiconductor patterns 110. Here, the first side surface may mean one side surface in the second direction D2. The first gate structure 130 may extend in the third direction D3 perpendicular to the first direction D1. In some embodiments, the semiconductor memory device may include a plurality of first gate structures 130, and the first gate structures 130 may be arranged in the second direction D2 perpendicular to the first direction D1 and intersecting the third direction D3. That is, the first gate structures 130 may extend in parallel to the third direction D3 and may be spaced apart from each other at regular intervals in the second direction D2. As used herein, “an element A overlaps an element B in a direction X” (or similar language) means that there is at least one straight line that extends in the direction X and intersects both the elements A and B.

The first gate structure 130 may include a first gate electrode 131 and the first gate insulating pattern 133. The first gate electrode 131 may be on (e.g., may cover and/or overlap) a portion of one side surface of the first gate insulating pattern 133 and may extend in the third direction D3. The first gate electrode 131 may be provided between a third capping pattern 145 and a fourth capping pattern 147, which will be described below. In some embodiments, the first gate electrode 131 may serve as a word line of the semiconductor memory device. The first gate electrode 131 may include a conductive material. The first gate electrode 131 may include, for example, a metal, a conductive metal nitride, a conductive metal silicide, a conductive metal oxide, polysilicon doped with impurities, or a combination thereof.

The first gate insulating pattern 133 may be provided between the first gate electrode 131 and the first side surfaces of the vertical semiconductor patterns 110. The first gate insulating pattern 133 may be on (e.g., may cover and/or overlap) the first side surfaces of the vertical semiconductor patterns 110 and may extend in the third direction D3. The first gate insulating pattern 133 may include an insulating material. The first gate insulating pattern 133 may include, for example, a silicon oxide, a silicon nitride, a silicon oxynitride, a high dielectric constant material having a dielectric constant higher than that of the silicon oxide, or a combination thereof.

In some embodiments, as illustrated in FIG. 1, the vertical semiconductor patterns 110 covered by odd-numbered ones of the first gate structures 130 may be connected to odd-numbered ones of the bit lines 210, and the vertical semiconductor patterns 110 covered by even-numbered ones of the first gate structures 130 may be connected to even-numbered ones of the bit lines 210. That is, the vertical semiconductor patterns 110 covered by the odd-numbered ones of the first gate structures 130 and the vertical semiconductor patterns 110 covered by the even-numbered ones of the first gate structures 130 may be arranged in a zigzag form (i.e., a zigzag shape) in the third direction D3 when viewed on a plane. For example, based on the two adjacent first gate structures 130, the vertical semiconductor patterns 110 connected to one of the two first gate structures 130 and the vertical semiconductor patterns 110 connected to the other one of the two first gate structures 130 may be offset from each other when viewed on a plane. Here, the offset may mean that the bit lines 210 connected to the vertical semiconductor patterns 110 in the same order among the vertical semiconductor patterns 110 connected to the first gate structures 130 are different from each other.

For example, the first gate structures 130 may include odd-numbered first gate structures 130 and even-numbered first gate structures 130 that are alternately arranged with one another along the second direction D2. That is, in the second direction D2, the first gate structures 130 may alternate between an odd-numbered first gate structure 130 and an even-numbered first gate structure 130, with each odd-numbered first gate structure 130 being adjacent to an even-numbered first gate structure 130, and each even-numbered first gate structure 130 being adjacent to an odd-numbered first gate structure 130. In some embodiments, first ones of the vertical semiconductor patterns 110 that are adjacent to the odd-numbered first gate structures 130 (e.g., in the second direction D2) may be connected to odd-numbered ones of the bit lines 210, and second ones of the vertical semiconductor patterns 110 that are adjacent to the even-numbered first gate structures 130 (e.g., in the second direction D2) may be connected to even-numbered ones of the bit lines 210. In some embodiments, first ones of the vertical semiconductor patterns 110 that are adjacent to the odd-numbered first gate structures 130 may be laterally offset from second ones of the vertical semiconductor patterns 110 that are adjacent to the even-numbered first gate structures 130. For example, first ones of the vertical semiconductor patterns 110 that are adjacent to the odd-numbered first gate structures 130 may not be aligned along the second direction D2 with second ones of the vertical semiconductor patterns 110 that are adjacent to the even-numbered first gate structures 130. For example, first ones of the vertical semiconductor patterns 110 that are adjacent to the odd-numbered first gate structures 130 may be shifted in the third direction D3 relative to second ones of the vertical semiconductor patterns 110 that are adjacent to the even-numbered first gate structures 130. In other words, a first one of the first gate structures 130 may be adjacent to a second one of the first gate structures 130 in the second direction D2, and a first one of the vertical semiconductor patterns 110 that is adjacent to the first one of the first gate structures 130 may not be aligned along the second direction D2 with (and may be shifted in the third direction D3 relative to) a second one of the vertical semiconductor patterns 110 that is adjacent to the second one of the first gate structures 130.

The second gate structure 150 may be provided between second side surfaces of the vertical semiconductor patterns 110. Here, the second side surfaces may be surfaces facing (i.e., opposite to) the first side surfaces of the vertical semiconductor patterns 110. That is, the second gate structure 150 may be on (e.g., may cover and/or overlap) some of the second side surfaces of the vertical semiconductor patterns 110. The second gate structure 150 may extend in the third direction D3 perpendicular to the first direction D1 and intersecting the second direction D2. In some embodiments, the semiconductor memory device may include a plurality of second gate structures 150, and the second gate structures 150 may be arranged in the second direction D2 perpendicular to the first direction D1 and intersecting the third direction D3. That is, the second gate structures 150 may extend in parallel to the third direction D3 and may be spaced apart from each other at regular intervals in the second direction D2.

The second gate structure 150 may include a second gate electrode 151 and two second gate insulating patterns 153. In some embodiments, the second gate electrode 151 may serve as a back gate of the semiconductor memory device. The second gate electrode 151 may extend in the third direction D3. The second gate electrode 151 may be provided between a first capping pattern 141 and a second capping pattern 143, which will be described below. The second gate electrode 151 may include a conductive material. The second gate electrode 151 may include, for example, a metal, a conductive metal nitride, a conductive metal silicide, a conductive metal oxide, polysilicon doped with impurities, or a combination thereof.

The second gate insulating patterns 153 may be provided on both (i.e., opposing) side surfaces of the second gate electrode 151 (e.g., in the second direction D2). The second gate insulating patterns 153 may be in contact with the second side surfaces of the vertical semiconductor patterns 110, respectively. That is, the second gate insulating patterns 153 may be provided between the second gate electrode 151 and the second side surfaces of the vertical semiconductor patterns 110. The second gate insulating patterns 153 may extend in the third direction D3. The second gate insulating patterns 153 may include an insulating material. The second gate insulating patterns 153 may include, for example, a silicon oxide, a silicon nitride, a silicon oxynitride, a high dielectric constant material having a dielectric constant higher than that of the silicon oxide, or a combination thereof.

The capacitor 310 may be provided on an upper surface of each of the vertical semiconductor patterns 110. Here, the upper surface may be a surface of the vertical semiconductor pattern 110 in the first direction D1. As used herein, the capacitor 310 may also be referred to as a capacitor structure 310. The capacitor 310 may store a signal received from a transistor inside a peripheral circuit structure (e.g., a row and column decoder, a sense amplifier, or the like) of the semiconductor memory device. The capacitor 310 may be used as an information storage element electrically connected to the transistor. For example, the capacitor 310 may store charges under control of the transistor. In some embodiments, the capacitor 310 may include a storage electrode 311, a capacitor dielectric film 313, and a plate electrode 315.

A plurality of storage electrodes 311 may be formed to be spaced apart from each other in the second direction D2 and the third direction D3 and may be in contact with the upper surface of each of the corresponding vertical semiconductor patterns 110. That is, the storage electrodes 311 may be spaced apart from each other at regular intervals in the second direction D2 and the third direction D3. In some embodiments, the storage electrodes 311 may be arranged in a zigzag form or a hexagonal honeycomb form offset from checkerboard arrangement in the second direction D2 and the third direction D3 when viewed on a plane. The storage electrode 311 may include a conductive material. The storage electrode 311 may include, for example, a metal, a metal nitride, a metal silicide, or a combination thereof. Accordingly, the capacitor 310 may be electrically connected to the vertical semiconductor patterns 110.

The capacitor dielectric film 313 may be provided on the storage electrodes 311, the first gate insulating patterns 133, the second gate insulating patterns 153, the second capping patterns 143, and the fourth capping patterns 147. That is, the capacitor dielectric film 313 may be conformally formed on the storage electrodes 311, the first gate insulating patterns 133, the second gate insulating patterns 153, the second capping patterns 143, and the fourth capping patterns 147. Unlike the illustration, the capacitor dielectric film 313 may include a plurality of films. The capacitor dielectric film 313 may include, for example, a silicon oxide, a silicon nitride, a silicon oxynitride, a high dielectric material including a metal, or a combination thereof.

The plate electrode 315 may be provided on the capacitor dielectric film 313. The plate electrode 315 may be in (e.g., may fill) an empty space between the storage electrodes 311. The plate electrode 315 may include at least one of an element semiconductor material film or a compound semiconductor material film. The plate electrode 315 may include doped n-type impurities or doped p-type impurities. The plate electrode 315 may include, for example, a metal, a metal nitride, a metal silicide, an impurity-doped silicon-germanium, or a combination thereof.

In some embodiments, a dielectric film 230 may be provided on the insulating pattern 219 in the direction opposite to the first direction D1. That is, the dielectric film 230 may be provided on the second surfaces 210b of the bit lines 210 and may be in (e.g., may fill) spaces between the bit lines 210. The dielectric film 230 may include, for example, a silicon oxide, a silicon nitride, a silicon oxynitride, and/or a high dielectric constant material including a metal. Accordingly, a process of forming a shielding pattern that may be provided between the bit lines 210 may be omitted. As a result, the process for forming the semiconductor memory device can be simplified.

A separation pattern 139 may be provided between the first gate electrodes 131 adjacent to each other and facing each other. The separation pattern 139 may electrically insulate the adjacent first gate electrodes 131 from each other. The separation pattern 139 may include an insulating material. The separation pattern 139 may include, for example, a silicon oxide, a silicon nitride, a silicon oxynitride, a high dielectric constant material having a dielectric constant higher than that of the silicon oxide, or a combination thereof.

The first capping pattern 141 may be provided between the bit line 210 and the second gate electrode 151. A lower surface of the first capping pattern 141 may be in contact with the buried conductive pattern 211 of the bit line 210. The first capping pattern 141 may be provided between lower ends of the second gate insulating patterns 153. The first capping pattern 141 may extend in parallel to the second gate electrode 151 in the third direction D3.

The second capping pattern 143 may be provided between the capacitor 310 and the second gate electrode 151. An upper surface of the second capping pattern 143 may be in contact with the storage electrode 311 and the capacitor dielectric film 313 of the capacitor 310. The second capping pattern 143 may be provided between upper ends of the second gate insulating patterns 153. The second capping pattern 143 may extend in parallel to the second gate electrode 151 in the third direction D3.

The third capping pattern 145 may be provided between the bit line 210, the first gate electrodes 131, and the separation pattern 139. A lower surface of the third capping pattern 145 may be in contact with the buried conductive pattern 211 of the bit line 210. The third capping pattern 145 may be provided between lower ends of the first gate insulating patterns 133. The third capping pattern 145 may extend in parallel to the first gate electrodes 131 in the third direction D3.

The fourth capping pattern 147 may be provided between the capacitor 310, the first gate electrodes 131, and the separation pattern 139. An upper surface of the fourth capping pattern 147 may be in contact with the capacitor dielectric film 313 of the capacitor 310. The fourth capping pattern 147 may be provided between upper ends of the first gate insulating patterns 133. The fourth capping pattern 147 may extend in parallel to the first gate electrodes 131 in the third direction D3.

Each of the first capping pattern 141, the second capping pattern 143, the third capping pattern 145, and the fourth capping pattern 147 may include an insulating material. Each of the first capping pattern 141, the second capping pattern 143, the third capping pattern 145, and the fourth capping pattern 147 may include, for example, a silicon oxide, a silicon nitride, a silicon oxynitride, or a combination thereof.

When an arrangement interval between the bit lines 210 is reduced, when all adjacent bit lines 210 are activated, a coupling phenomenon may occur, and noise and a parasitic capacitance may increase. To prevent this, a shielding pattern may be formed between the bit lines 210. However, in the semiconductor memory device according to some embodiments of the present disclosure, different vertical semiconductor patterns 110 may be connected to adjacent bit lines 210 such that the adjacent bit lines 210 are not simultaneously activated. In other words, the vertical semiconductor patterns 110 connected to the even-numbered bit lines 210 between the odd-numbered bit lines 210 adjacent to each other may be laterally offset from the vertical semiconductor patterns 110 connected to the odd-numbered bit lines 210 adjacent to each other. In this way, as the vertical semiconductor patterns 110 are arranged to be offset from the bit lines 210 according to positions thereof, two adjacent bit lines 210 are not simultaneously activated. Accordingly, even while the arrangement interval between the bit lines 210 is reduced, a coupling phenomenon that occurs between the adjacent bit lines 210 without forming the shielding pattern may be improved. As a result, parasitic capacitances of the bit lines 210 may be reduced, a process may be simplified, and noise may be improved.

According to some embodiments, the vertical semiconductor patterns 110 connected to the first gate structures 130 may be offset from each other at a single line interval, but embodiments of the present disclosure are not limited thereto. For example, the first gate structures 130 arranged in the third direction D3 may be offset at intervals of two or three or more lines.

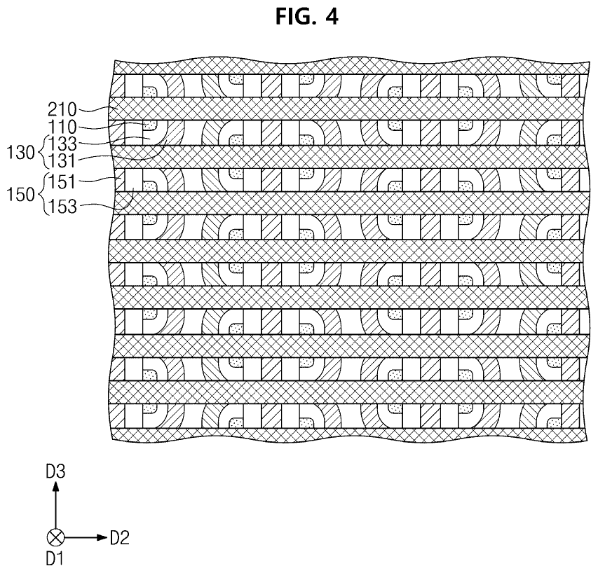

FIG. 4 is a rear view illustrating the semiconductor memory device according to some embodiments of the present disclosure. For convenience of description, differences between the following embodiments and the above-described embodiments will be mainly described.

Referring to FIG. 4, the vertical semiconductor patterns 110 covered by (4N-3)^{th} and (4N-2)^{th} ones of the first gate structures 130 may be connected to the odd-numbered ones of the bit lines 210, and the vertical semiconductor patterns 110 covered by (4N-1)^{th} and 4N^{th} ones of the first gate structures 130 may be connected to the even-numbered ones of the bit lines 210. (Here, “N” is a natural number.) That is, the (4N-3)^{th} and (4N-2)^{th} ones of the first gate structures 130 and the (4N-1)^{th} and 4N^{th} ones of the first gate structures 130 may be arranged in a zigzag form in the third direction D3 when viewed on a plane. Through this arrangement, capacitances of the bit lines 210 may be reduced, and noise may be improved.

For example, the first gate structures 130 may include N first gate structures 130 that are sequentially arranged along the second direction D2, with “N” being a natural number. The first gate structures 130 may extend in the third direction D3 and may be spaced apart from each other in the second direction D2. In some embodiments, first ones of the vertical semiconductor patterns 110 that are adjacent to (4N-3)^{th} and (4N-2)^{th} ones of the first gate structures 130 (e.g., in the second direction D2) may be connected to odd-numbered ones of the bit lines 210, and second ones of the vertical semiconductor patterns 110 that are adjacent to (4N-1)^{th} and 4N^{th} ones of the first gate structures 130 (e.g., in the second direction D2) may be connected to even-numbered ones of the bit lines 210. For example, a pair of vertical semiconductor patterns 110 that are adjacent to each other in the second direction D2, with a second gate structure 150 therebetween, may be connected to a same bit line 210.

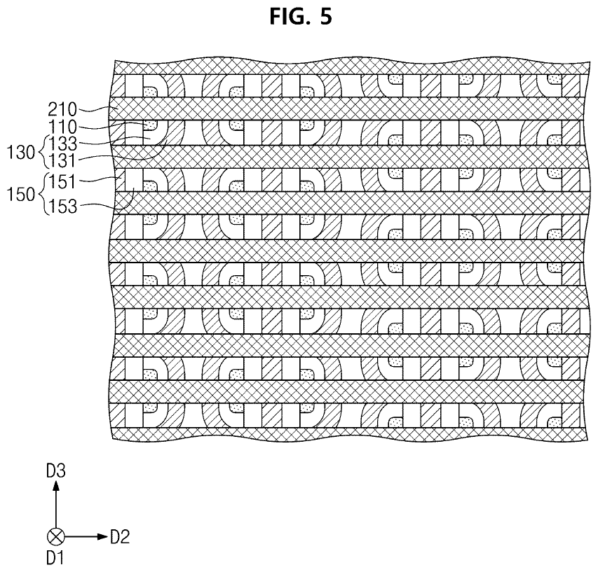

FIG. 5 is a rear view illustrating the semiconductor memory device according to some embodiments of the present disclosure. For convenience of description, differences between the following embodiments and the above-described embodiments will be mainly described.

Referring to FIG. 5, the vertical semiconductor patterns 110 covered by (6N-5)^{th}, (6N-4)^{th}, and (6N-3)^{th} ones of the first gate structures 130 may be connected to the odd-numbered ones of the bit lines 210, and the vertical semiconductor patterns 110 covered by (6N-2)^{th}, (6N-1)th, and 6N^{th} ones of the first gate structures 130 may be connected to the even-numbered ones of the bit lines 210. (Here, “N” is a natural number.) That is, the (6N-5)^{th}, (6N-4)^{th}, and (6N-3)^{th} ones of the first gate structures 130 and the (6N-2)^{th}, (6N-1)^{th}, and 6N^{th} ones of the first gate structures 130 may be arranged in a zigzag form in the third direction D3 when viewed on a plane. For example, first ones of the vertical semiconductor patterns 110 that are adjacent to (6N-5)th, (6N-4)^{th}, and (6N-3)^{th} ones of the first gate structures 130 may be connected to odd-numbered ones of the bit lines 210, and second ones of the vertical semiconductor patterns 110 that are adjacent to (6N-2)^{th}, (6N-1)^{th}, and 6N^{th} ones of the first gate structures 130 may be connected to even-numbered ones of the bit lines 210. Through this arrangement, capacitances of the bit lines 210 may be reduced, and noise may be improved.

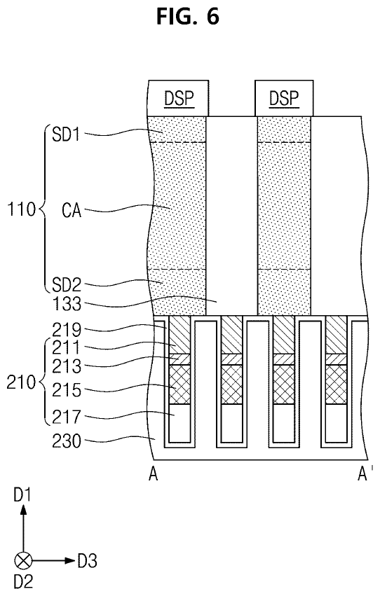

FIG. 6 is a cross-sectional view taken along line A-A′ of FIG. 1 according to some embodiments of the present disclosure. For convenience of description, differences between the following embodiments and the above-described embodiments will be mainly described.

Referring to FIG. 6, data storage patterns DSP may be provided on the upper surfaces of the vertical semiconductor patterns 110. For example, the semiconductor memory device may include the data storage patterns DSP instead of the capacitor 310 described above with reference to FIGS. 1 to 3. The data storage patterns DSP may be electrically connected to the vertical semiconductor patterns 110. When viewed on a plane, the data storage patterns DSP may be spaced apart from each other at regular intervals in the second direction D2 and the third direction D3. That is, the data storage patterns DSP included in the semiconductor memory device according to some embodiments of the present disclosure may be arranged in a zigzag structure or a honeycomb structure when viewed on a plane.

In some embodiments, the data storage patterns DSP may be variable resistance patterns that may be switched between two resistance states by an electrical pulse applied to a memory element. For example, the data storage patterns DSP may include phase-change materials, perovskite compounds, transition metal oxides, magnetic materials, ferromagnetic materials, or antiferromagnetic materials of which crystal states are changed according to the amount of current.

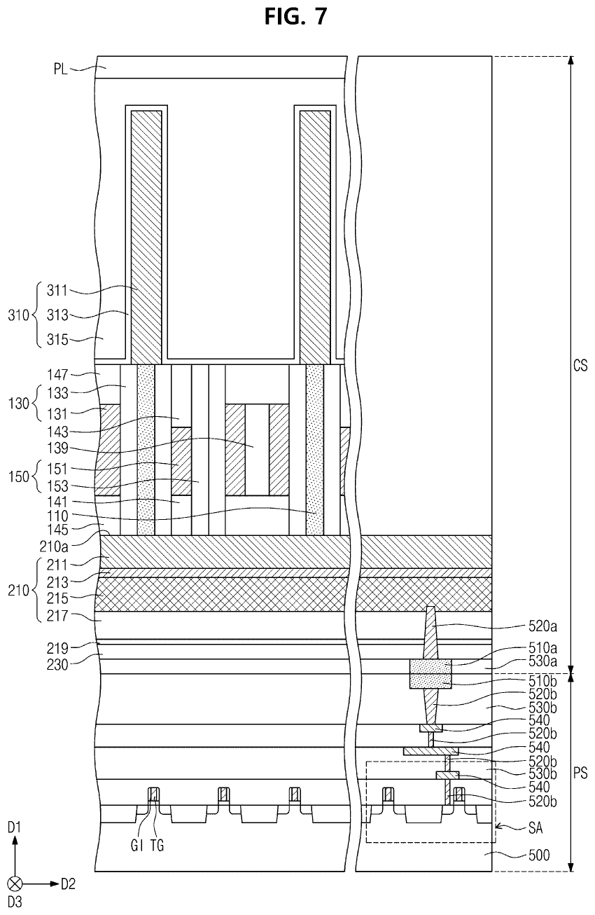

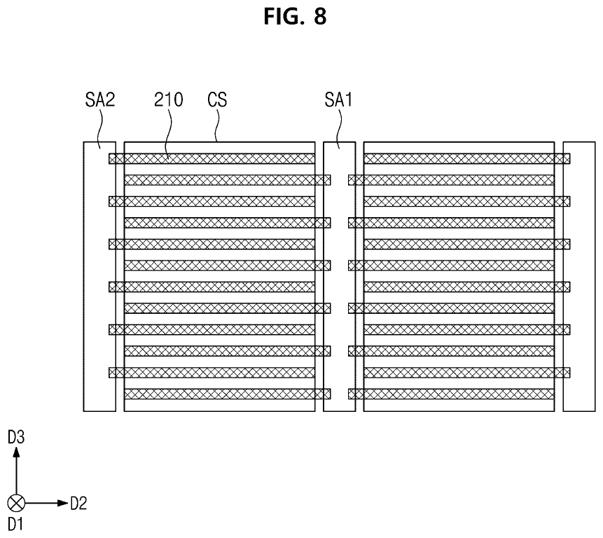

FIG. 7 is a cross-sectional view illustrating the semiconductor memory device according to some embodiments of the present disclosure, and FIG. 8 is a rear view illustrating the semiconductor memory device according to some embodiments of the present disclosure. For convenience of description, differences between the following embodiments and the above-described embodiments will be mainly described.

Referring to FIGS. 7 and 8, the semiconductor memory device according to some embodiments of the present disclosure may include a peripheral circuit structure PS and a cell array structure CS connected to the peripheral circuit structure PS. The semiconductor memory device may have a chip to chip (C2C) structure. The C2C structure may mean that an upper chip including the cell array structure CS is manufactured on a first substrate, a lower chip including the peripheral circuit structure PS is manufactured on a third substrate, and then the upper chip and the lower chip are connected to each other by a bonding method. For example, the bonding method may mean a method of electrically connecting a bonding pad formed on an uppermost metal layer of the upper chip and a bonding pad formed on an uppermost metal layer of the lower chip. For example, when the bonding pad is formed of copper (Cu), the bonding method may be a Cu-to-Cu bonding method, and the bonding pad may be also formed of aluminum (Al) or tungsten (W). In more detail, the cell array structure CS may be provided on the peripheral circuit structure PS. As described above with reference to FIGS. 1 to 3, in the cell array structure CS, the vertical semiconductor patterns 110 as cell transistors of each memory cell and the capacitor 310 as a data storage element of each memory cell may be provided, and a passivation film PL may be provided on the capacitor 310.

As illustrated in FIG. 7, first bonding pads 510a may be provided on a second interlayer insulating film 530a on a lowermost layer of the cell array structure CS. The first bonding pads 510a may be electrically connected to the first gate electrode 131 and the second gate electrode 151 and the bit lines 210 through first contact plugs 520a. The first bonding pads 510a may be in direct contact with and bonded to second bonding pads 510b of the peripheral circuit structure PS. The peripheral circuit structure PS may include a core and peripheral circuits formed on a third substrate 500. Here, the core may refer to a circuit in which the memory cells of the semiconductor memory device are connected, and the peripheral circuit may refer to other circuits. The core and the peripheral circuits may include row and column decoders, sense amplifiers SA, and control logics. For example, the sense amplifiers SA may be formed in the third substrate 500. The third substrate 500 may be on lower surfaces (i.e., second surfaces) of the bit lines 210. The second bonding pads 510b may be provided on an uppermost layer of third interlayer insulating films 530b of the peripheral circuit structure PS. The second bonding pads 510b may be electrically connected to the core and the peripheral circuits of the semiconductor memory device through peripheral wiring lines 540 and second contact plugs 520b.

In some embodiments, the peripheral circuit structure PS of the semiconductor memory device may include a first sense amplifier SA1 and a second sense amplifier SA2. The first sense amplifier SA1 and the second sense amplifier SA2 may sense changes in voltages of the bit lines 210 selected from the plurality of bit lines 210 and amplify and output the changes in the voltages.

As illustrated in FIG. 8, the cell array structure CS may include the plurality of bit lines 210, and each of the bit lines 210 included in the cell array structure CS may be connected to the first sense amplifier SA1 or the second sense amplifier SA2. In some embodiments, the first sense amplifier SA1 may be connected to the even-numbered bit lines 210, and the second sense amplifier SA2 may be connected to the odd-numbered bit lines 210. Accordingly, when the semiconductor memory device is operated, the first sense amplifier SA1 may activate the even-numbered bit lines 210. Further, when the even-numbered bit lines 210 are activated, the odd-numbered bit lines 210, to which the first sense amplifier SA1 is not connected, may be pre-charged.

Likewise, when the semiconductor memory device is operated, the second sense amplifier SA2 may activate the odd-numbered bit lines 210. Further, when the odd-numbered bit lines 210 are activated, the even-numbered bit lines 210, to which the second sense amplifier SA2 is not connected, may be pre-charged.

Accordingly, when one of the adjacent bit lines 210 is activated, the other adjacent bit line 210 may be pre-charged, and a coupling phenomenon occurring when both adjacent bit lines 210 are activated may be reduced. As a result, the parasitic capacitances of the bit lines 210 may be reduced, and noise may be improved.

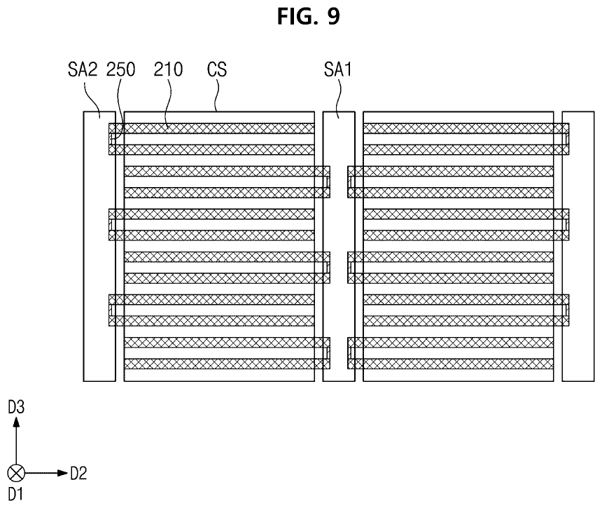

FIG. 9 is a rear view illustrating the semiconductor memory device according to some embodiments of the present disclosure. For convenience of description, differences between the following embodiments and the above-described embodiments will be mainly described.

Referring to FIG. 9, bit line contacts 250 may be provided inside the first sense amplifier SA1 and the second sense amplifier SA2. Here, the bit line contact 250 may be a metal wiring line. The bit line contacts 250 may connect distal ends of the adjacent bit lines 210 inside each of the first sense amplifier SA1 and the second sense amplifier SA2 in a pair. Accordingly, the adjacent bit lines 210 connected in each of the first sense amplifier SA1 and the second sense amplifier SA2 may form bit line pairs electrically connected through the bit line contacts 250, respectively. For example, adjacent ones of the bit lines 210 (e.g., in the third direction D3) may be grouped into pairs, with the pairs alternately arranged with one another along the third direction D3 as odd-numbered bit line pairs and even-numbered bit line pairs. In more detail, the first sense amplifier SA1 may be connected to even-numbered bit line pairs, and the second sense amplifier SA2 may be connected to odd-numbered bit line pairs. For example, while being connected to the first sense amplifier SA1, the bit line contacts 250 may be provided at distal ends of third and fourth bit lines 210 adjacent to each other and seventh and eighth bit lines 210 adjacent to each other. Accordingly, the third and fourth bit lines 210 and the seventh and eighth bit lines 210 may be electrically connected in pairs. The odd-numbered bit line pairs connected to the second sense amplifier SA2 may also be electrically connected as the bit line contacts 250 are provided in the same manner as the first sense amplifier SA1. Accordingly, interference between the bit lines 210 may be reduced, and noise may be improved.

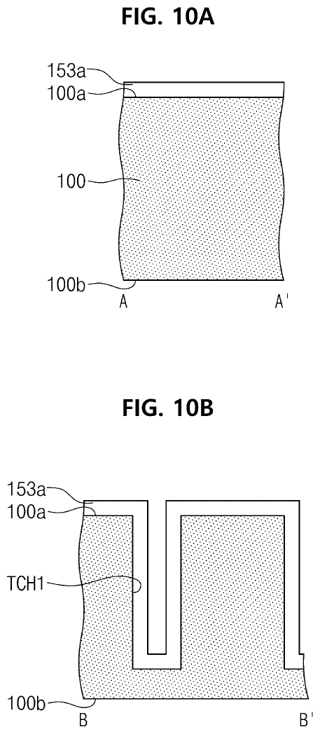

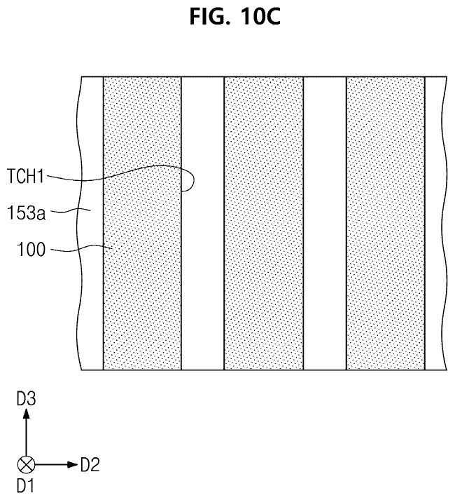

FIGS. 10A, 10B, 10C, 11A, 11B, 11C, 12A, 12B, 12C, 13A, 13B, 13C, 14A, 14B, 14C, 15A, 15B, 15C, 16A, 16B, 16C, 17A, 17B, 18A, 18B, 19A, 19B, 20A, 20B, 21A, 21B, 22A, and 22B are cross-sectional views and rear views illustrating a method of manufacturing a semiconductor memory device according to some embodiments of the present disclosure.

In more detail, FIGS. 10A, 11A, 12A, 13A, 14A, 15A, 16A, 17A, 18A, 19A, 20A, 21A, and 22A are cross-sectional views corresponding to line A-A′ of FIG. 1, which illustrate a method of manufacturing a semiconductor memory device according to some embodiments of the present disclosure. FIGS. 10B, 11B, 12B, 13B, 14B, 15B, 16B, 17B, 18B, 19B, 20B, 21B, and 22B are cross-sectional views corresponding to line B-B′ of FIG. 1, which illustrate the method of manufacturing a semiconductor memory device according to some embodiments of the present disclosure. FIGS. 10C, 11C, 12C, 13C, 14C, 15C, and 16C are rear views corresponding to FIG. 1, which illustrate the method of manufacturing a semiconductor memory device according to some embodiments of the present disclosure.

Referring to FIGS. 10A to 10C, a first substrate 100 may be prepared. The first substrate 100 may be, for example, a silicon substrate, a germanium substrate, and/or a silicon-germanium substrate. The first substrate 100 may have a first surface 100a and a second surface 100b facing (i.e., opposite to) the first surface 100a.

A patterning process may be performed on the first surface 100a of the first substrate 100 to form first trenches TCH1. The first trenches TCH1 may extend from the first surface 100a toward the second surface 100b and may extend in the third direction D3 perpendicular to the first surface 100a when viewed on a plane. Next, a second gate insulating film 153a may be conformally formed on the first surface 100a of the first substrate 100 and on inner surfaces of the first trenches TCH1. The second gate insulating film 153a may be formed through at least one of an oxidation process or a deposition process.

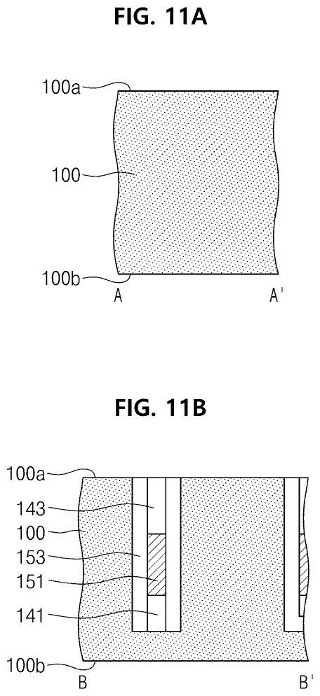

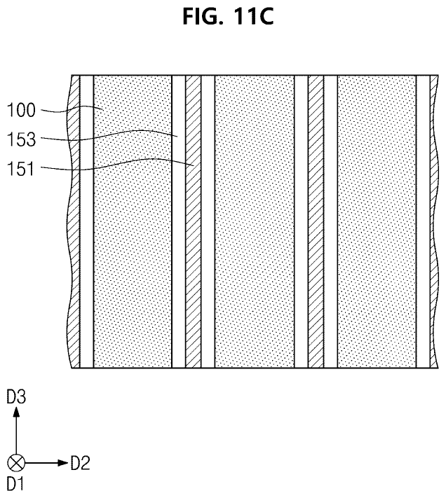

Referring to FIGS. 11A to 11C, an etch-back process may be performed on a portion of the second gate insulating film 153a, and accordingly, the second gate insulating patterns 153 may be formed on inner walls of the first trenches TCH1. The second gate insulating patterns 153 may extend in the third direction D3 when viewed on a plane. A first capping film may be formed on lower surfaces of the second gate insulating patterns 153 and the first trenches TCH1, and a portion of the first capping film may be removed to form the first capping patterns 141. The first capping patterns 141 may be formed through an etch-back process.

A second gate electrode film may be formed on the first capping patterns 141, the second gate insulating patterns 153, and the first surface 100a of the first substrate 100 to be in (e.g., to fill) the first trenches TCH1. Thereafter, an etching process may be performed on the second gate electrode film to form the second gate electrodes 151. The etching process may be an etch-back process. The second gate electrodes 151 may be provided between the second gate insulating patterns 153 when viewed on a plane, and each of the second gate electrodes 151 may extend in the third direction D3.

A second capping film may be formed on the second gate insulating patterns 153 and the second gate electrodes 151 to be in (e.g., to fill) the first trenches TCH1. An etching process may be performed on the second capping film to expose the first substrate 100. The etching process may be performed through a chemical mechanical polishing (CMP) process.

Accordingly, the second capping patterns 143 may be formed. Each of the second capping patterns 143 may be formed between the second gate insulating patterns 153 and the second gate electrodes 151 that are present in each of the first trenches TCH1.

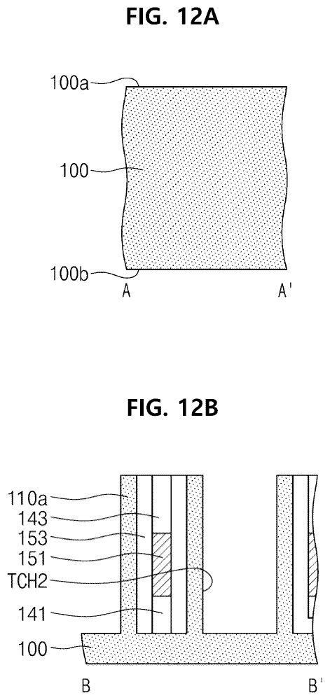

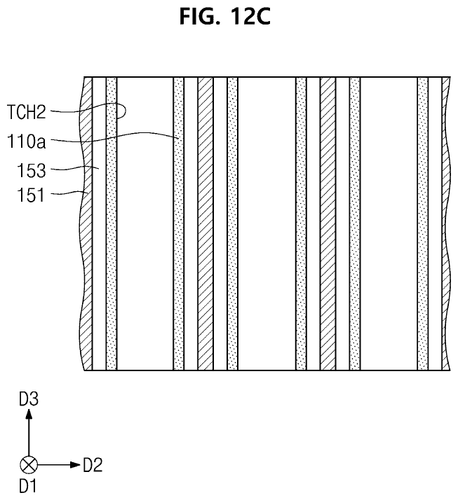

Referring to FIGS. 12A to 12C, a patterning process may be performed on the first surface 100a of the first substrate 100 to form second trenches TCH2. The second trenches TCH2 may extend from the first surface 100a toward the second surface 100b and may extend in the third direction D3 perpendicular to the first surface 100a when viewed on a plane. The second trenches TCH2 may be formed between the second gate insulating patterns 153 and the second gate electrodes 151 spaced apart from each other when viewed on a plane. Accordingly, preliminary vertical semiconductor patterns 110a may be formed. The preliminary vertical semiconductor patterns 110a may extend in the third direction D3 perpendicular to the first surface 100a when viewed on a plane.

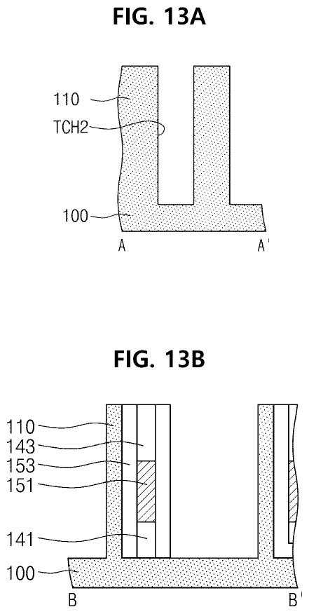

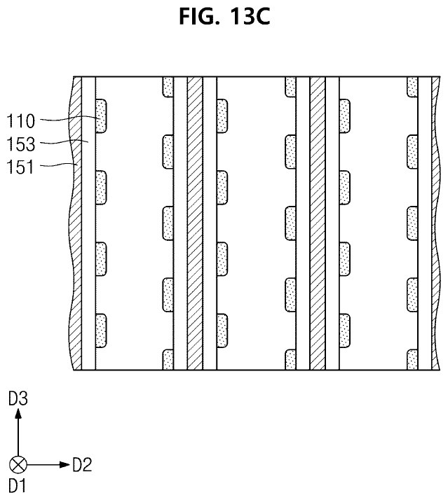

Referring to FIGS. 13A to 13C, after an etching mask (not shown) is formed to be on (e.g., to cover and/or overlap) portions of the preliminary vertical semiconductor patterns 110a, the second gate insulating patterns 153 and the second capping patterns 143, the patterning process may be performed on the first surface 100a of the first substrate 100 to form the vertical semiconductor patterns 110. Each of the vertical semiconductor patterns 110 may extend in the first direction D1 and the vertical semiconductor patterns 110 may be spaced apart from each other when viewed on a plane. In some embodiments, the vertical semiconductor patterns 110 may have a zigzag arrangement or a honeycomb arrangement when viewed on a plane.

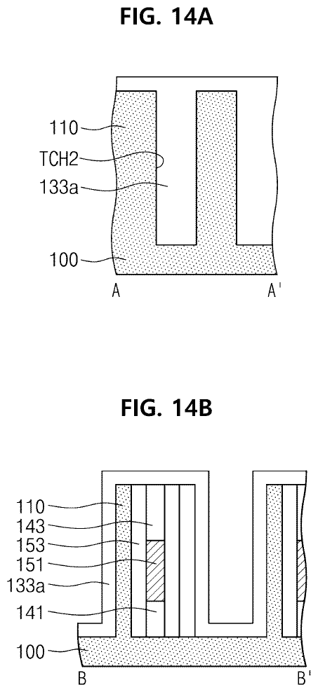

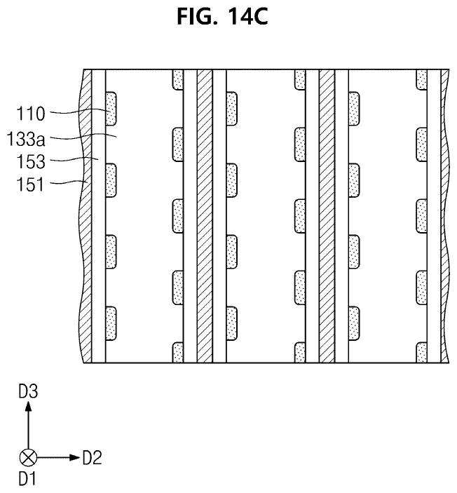

Referring to FIGS. 14A to 14C, a first gate insulating film 133a may be conformally formed on the first surface 100a of the first substrate 100, the vertical semiconductor patterns 110, the second gate insulating patterns 153, and inner surfaces of the second trenches TCH2. The first gate insulating film 133a may be formed through at least one of an oxidation process or a deposition process.

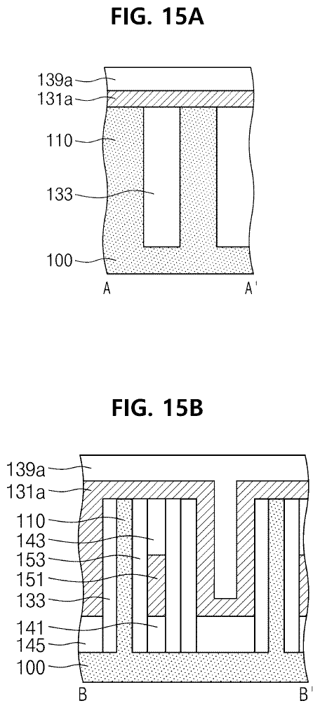

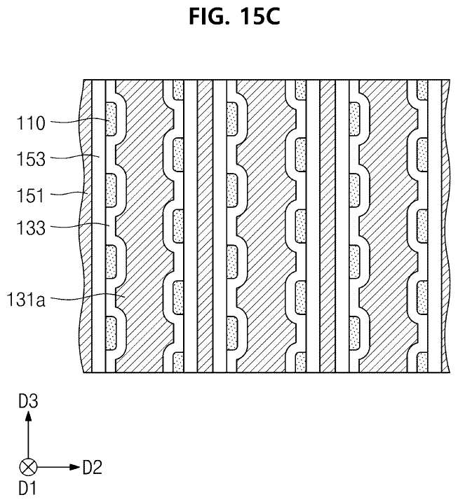

Referring to FIGS. 15A to 15C, an etch-back process may be performed on a portion of the first gate insulating film 133a, and accordingly, the first gate insulating patterns 133 may be formed on one side surface of the second gate insulating patterns 153, the first side surfaces of the vertical semiconductor patterns 110, and inner walls of the second trenches TCH2. The first gate insulating patterns 133 may be on (e.g., may cover and/or overlap) the first side surfaces of the vertical semiconductor patterns 110 and may extend in the third direction D3 when viewed on a plane.

A third capping film may be formed on lower surfaces of the first gate insulating patterns 133 and the second trenches TCH2, and a portion of the third capping film may be removed to form the third capping patterns 145. The third capping patterns 145 may be formed through an etch-back process.

A first gate electrode film 131a may be conformally formed on the third capping patterns 145, the first gate insulating patterns 133, and the first surface 100a of the first substrate 100. Thereafter, a separation film 139a may be formed on the first gate electrode film 131a.

Accordingly, the separation film 139a may be in (e.g., may fill) the second trenches TCH2. The first gate electrode film 131a and the separation film 139a may be formed through at least one of an oxidation process or a deposition process.

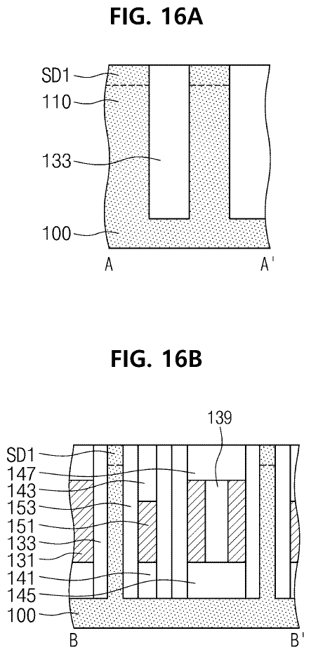

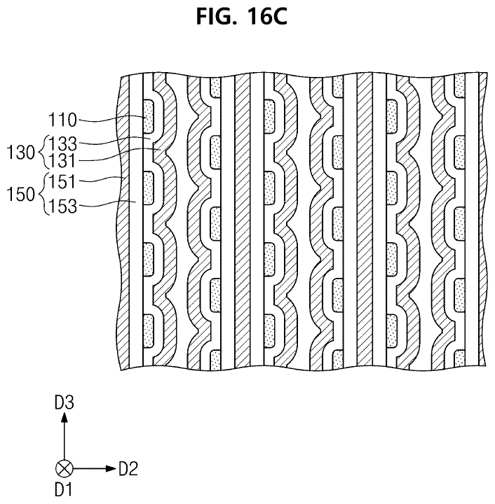

Referring to FIGS. 16A to 16C, an etching process may be performed on the first surface 100a of the first substrate 100 to form the first gate electrodes 131 and the separation patterns 139. The etching process may be an etch-back process. Each of the separation patterns 139 may be provided between the first gate electrodes 131 to electrically isolate the first gate electrodes 131. The first gate electrodes 131 and the separation patterns 139 may be provided between the first gate insulating patterns 133 when viewed on a plane, and each thereof may extend in the third direction D3.

A fourth capping layer may be formed on the first gate insulating patterns 133, the first gate electrodes 131, and the separation patterns 139 to be in (e.g., to fill) the second trenches TCH2. An etching process may be performed on the fourth capping layer to expose the first substrate 100. The etching process may be performed through a chemical mechanical polishing (CMP) process. Accordingly, the fourth capping patterns 147 may be formed. Each of the fourth capping patterns 147 may be formed between the first gate insulating patterns 133 that are present in each of the second trenches TCH2 and on the first gate electrodes 131 and the separation patterns 139.

Thereafter, an ion implantation process may be performed at an upper end of each of the vertical semiconductor patterns 110 to form the first source/drain area SD1. The upper ends of the vertical semiconductor patterns 110 may be positioned at a higher level than those of the first gate electrodes 131 and the second gate electrodes 151 (e.g., relative to the second surface 100b of the first substrate 100).

Hereinafter, unless otherwise mentioned, in operations of the method of manufacturing a semiconductor memory device according to some embodiments of the present disclosure, the rear view corresponding to FIG. 1 may be substantially the same as that of FIG. 16C.

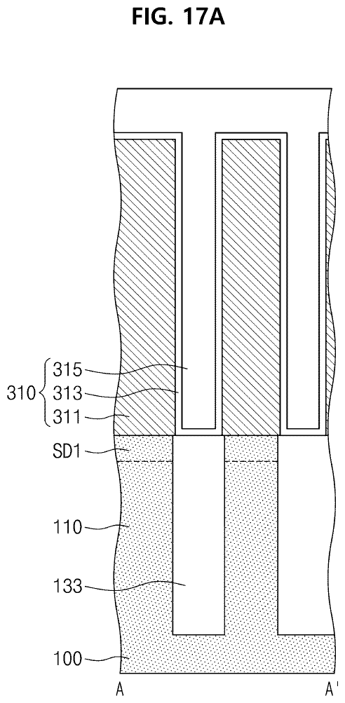

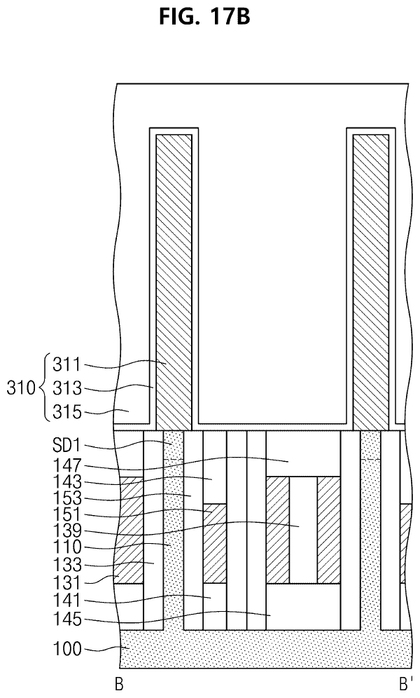

Referring to FIGS. 17A and 17B, the storage electrodes 311 may be formed on the upper surfaces of the vertical semiconductor patterns 110, and the capacitor dielectric film 313 that conformally extends on (e.g., conformally covers and/or overlaps) the surfaces of the storage electrodes 311 may be formed. Next, the plate electrode 315 may be formed on the capacitor dielectric film 313. The storage electrodes 311 and the capacitor dielectric film 313 sequentially stacked may form the capacitor 310 together with the plate electrode 315.

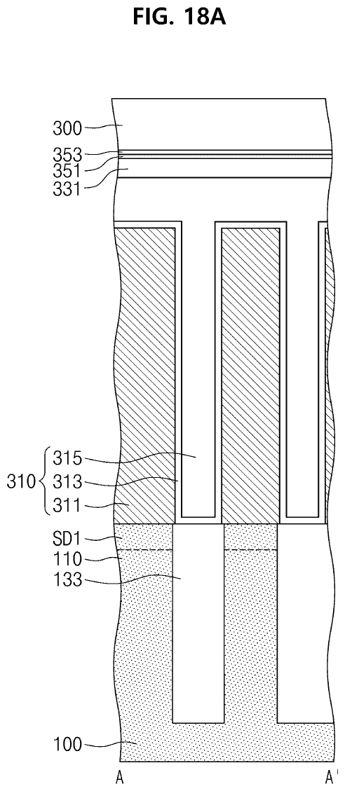

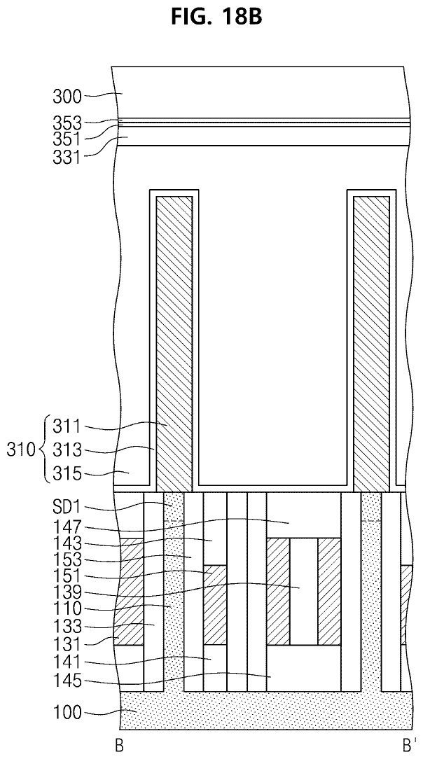

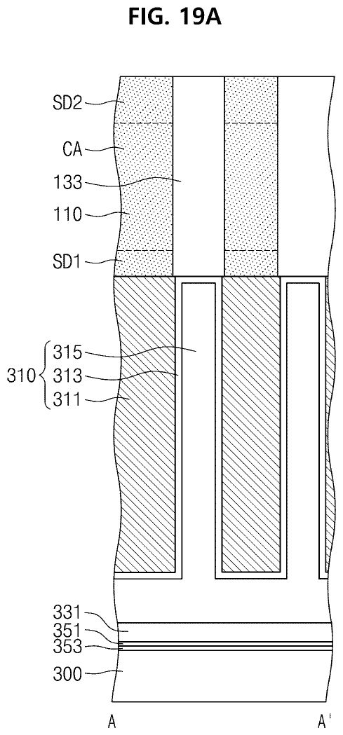

Referring to FIGS. 18A and 18B, after a first interlayer insulating film 331 is formed on the capacitor 310, a first joining film 351 may be formed on the first interlayer insulating film 331.

Further, a second joining film 353 may be formed on a second substrate 300, and after inverting this component, the second joining film 353 and the first joining film 351 may be brought into contact with each other to join the first substrate 100 and the second substrate 300 to each other.

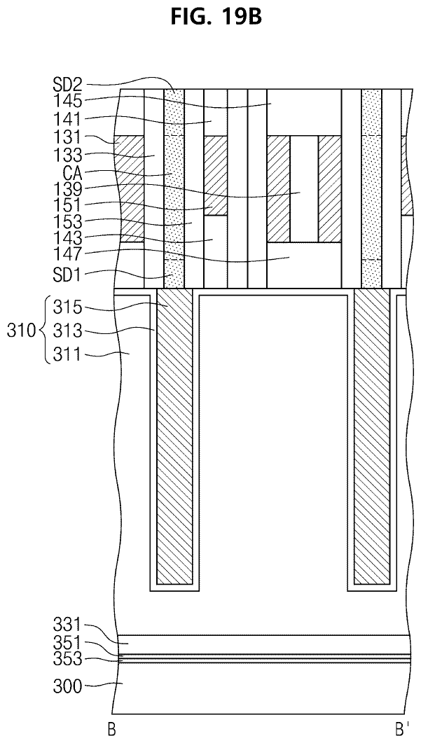

Referring to FIGS. 19A and 19B, the first substrate 100 and the second substrate 300 that are joined to each other may be inverted. In other words, the structure shown in FIGS. 18A and 18B may be inverted (i.e., flipped). Thereafter, the second surface 100b of the first substrate 100 may be polished to expose the vertical semiconductor patterns 110. In some embodiments, the second surface 100b of the first substrate 100 may be polished through a chemical mechanical polishing (CMP) process. In some embodiments, the first substrate 100 may be removed through the CMP process, but the present disclosure is not limited thereto.

An ion implantation process may be performed at a lower end of each of the vertical semiconductor patterns 110 to form the second source/drain area SD2. Accordingly, the channel area CA may be defined between the first source/drain area SD1 and the second source/drain area SD2.

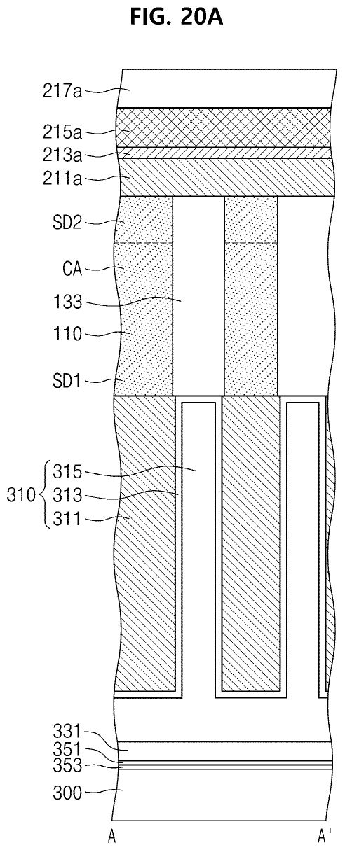

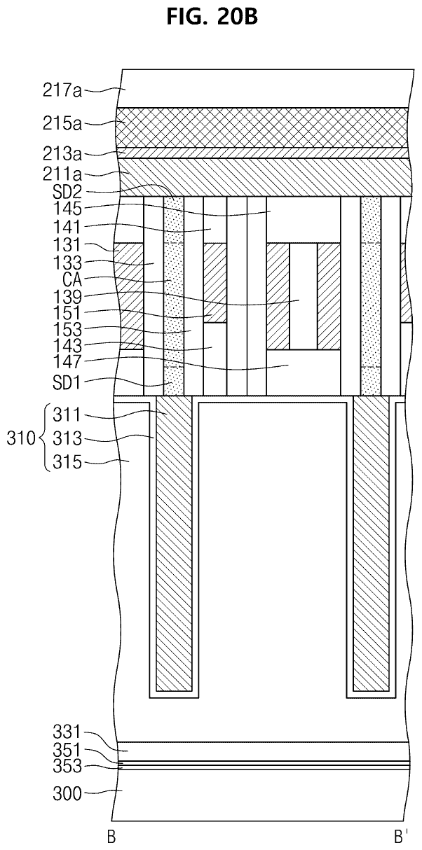

Referring to FIGS. 20A and 20B, a buried conductive film 211a may be provided on the vertical semiconductor patterns 110 (e.g., on the second source/drain area SD2). Next, a contact film 213a, a metal film 215a, and a hard mask film 217a may be sequentially formed on the buried conductive film 211a. The buried conductive film 211a, the contact film 213a, the metal film 215a, and the hard mask film 217a may be formed through at least one of an oxidation process or a deposition process.

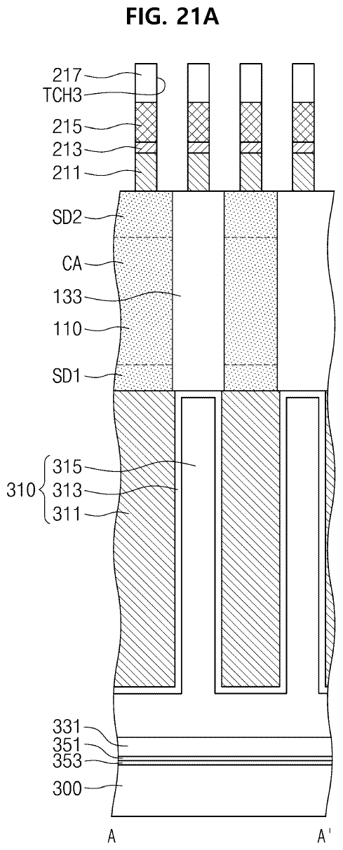

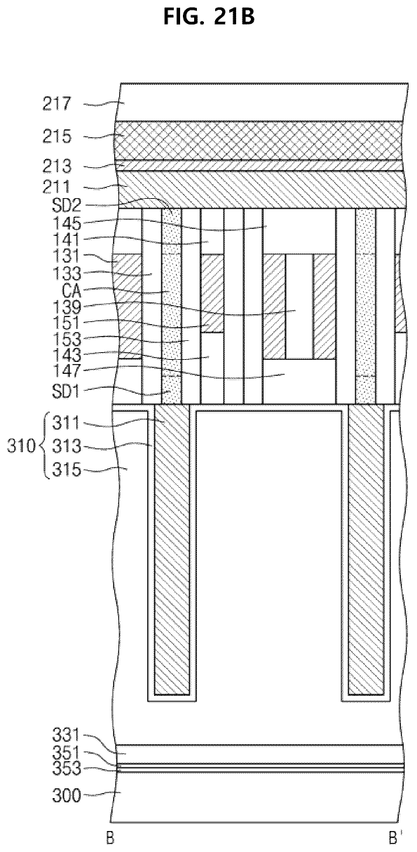

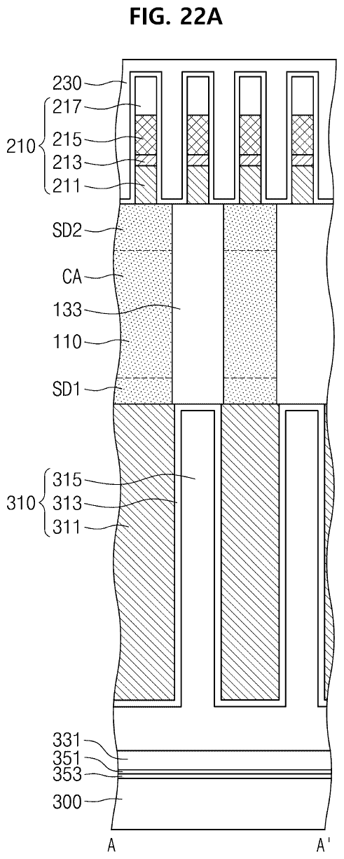

Referring to FIGS. 1, 21A, and 21B, a mask pattern (not shown) having a line shape extending in the second direction D2 may be formed on the hard mask film 217a, and the hard mask film 217a, the metal film 215a, the contact film 213a, and the buried conductive film 211a may be sequentially anisotropically etched using the mask pattern, to thereby form a hardmask pattern 217, a metal pattern 215, a contact pattern 213, and a buried conductive pattern 211, respectively. Accordingly, third trenches TCH3 extending from the vertical semiconductor patterns 110 and/or the first gate insulating patterns 133 may be formed. As a result, the bit lines 210 extending in the second direction D2 may be formed. Each bit line 210 may include the buried conductive pattern 211, the contact pattern 213, the metal pattern 215, and the hardmask pattern 217. The bit lines 210 may be spaced apart from each other in the third direction D3 by the third trenches TCH3 when viewed on a plane.

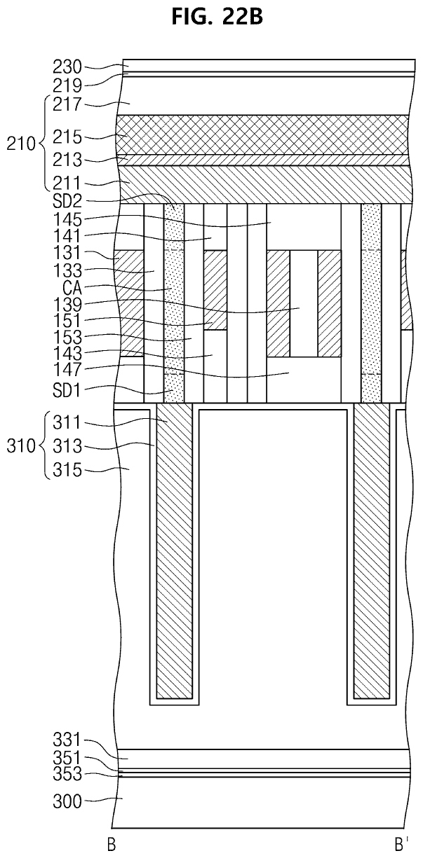

Referring to FIGS. 1 to 3, 22A, and 22B, after the bit lines 210 are formed, the insulating pattern 219 may be conformally formed on the third trenches TCH3. That is, the insulating pattern 219 may be conformally formed on the second surfaces 210b of the bit lines 210, the upper surfaces of the first gate insulating patterns 133, and the upper surfaces of the vertical semiconductor patterns 110. A formation thickness of the insulating pattern 219 may be smaller than a half of an interval between the bit lines 210 adjacent to each other. Thereafter, the dielectric film 230 may be formed on the insulating pattern 219 to be in (e.g., to fill) the third trenches TCH3. That is, the dielectric film 230 may be provided on the second surfaces 210b of the bit lines 210 and may be in (e.g., may fill) spaces between the bit lines 210. The insulating pattern 219 and the dielectric film 230 may be formed through at least one of an oxidation process or a deposition process. In some embodiments, the second substrate 300, the second joining film 353, and/or the first joining film 351 may be removed and the structure shown in FIGS. 22A and 22B may be inverted (i.e., flipped) after the insulating pattern 219 and the dielectric film 230 are formed, but the present disclosure is not limited thereto.

According to example embodiments of the present disclosure, different vertical semiconductor patterns may be connected to adjacent bit lines so that the adjacent bit lines are not simultaneously activated. In other words, vertical semiconductor patterns connected to even-numbered bit lines between odd-numbered bit lines adjacent to each other may be laterally offset from vertical semiconductor patterns connected to the odd-numbered bit lines adjacent to each other. Accordingly, even while an arrangement interval between the bit lines is reduced, a coupling phenomenon that occurs between the adjacent bit lines without forming a shielding pattern may be improved. As a result, parasitic capacitances of the bit lines may be reduced, a process may be simplified, and noise may be improved.

Further, a semiconductor memory device according to example embodiments of the present disclosure may include a first sense amplifier and a second sense amplifier, the first sense amplifier may be connected to the even-numbered bit lines, and the second sense amplifier may be connected to the odd-numbered bit lines. When one of the adjacent bit lines is activated as the semiconductor memory device is operated, the other adjacent bit line may be pre-charged. Accordingly, a coupling phenomenon occurring when all the adjacent bit lines are activated may be reduced. As a result, parasitic capacitances of the bit lines may be reduced, and noise may be improved.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms.

Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

Although the description has been made above with reference to example embodiments of the present disclosure, those skilled in the art will understand that the present disclosure may be variously modified and changed without departing from the scope of the present disclosure described in the appended claims.

Thus, the technical scope of the present disclosure should not be limited to the contents described in the detailed description of the specification but should be defined by the appended claims.

What is claimed is:

1. A semiconductor memory device comprising:
vertical semiconductor patterns extending in a first direction;
a plurality of bit lines electrically connected to lower surfaces of the vertical semiconductor patterns, each of the bit lines extending in a second direction that is perpendicular to the first direction; and
a plurality of first gate structures on first side surfaces of the vertical semiconductor patterns, each of the first gate structures extending in a third direction that is perpendicular to the first direction and intersects the second direction,
wherein the bit lines include odd-numbered bit lines and even-numbered bit lines that are alternately arranged with one another along the third direction, and
wherein first ones of the vertical semiconductor patterns that are electrically connected to the even-numbered bit lines are laterally offset from second ones of the vertical semiconductor patterns that are electrically connected to the odd-numbered bit lines.

2. The semiconductor memory device of claim 1, wherein the bit lines have first surfaces electrically connected to the lower surfaces of the vertical semiconductor patterns and second surfaces opposite to the first surfaces, and
wherein the semiconductor memory device further comprises a dielectric film on the second surfaces of the bit lines and between adjacent ones of the bit lines.

3. The semiconductor memory device of claim 2, further comprising:
a substrate on the second surfaces of the bit lines; and
a first sense amplifier and a second sense amplifier at least partially in the substrate,
wherein the first sense amplifier is electrically connected to the even-numbered bit lines, and
wherein the second sense amplifier is electrically connected to the odd-numbered bit lines.

4. The semiconductor memory device of claim 3, wherein, when the semiconductor memory device is operated, the first sense amplifier is configured to activate the even-numbered bit lines, and
wherein, when the even-numbered bit lines are activated, the odd-numbered bit lines are configured to be pre-charged.

5. The semiconductor memory device of claim 3, wherein, when the semiconductor memory device is operated, the second sense amplifier is configured to activate the odd-numbered bit lines, and
wherein, when the odd-numbered bit lines are activated, the even-numbered bit lines are configured to be pre-charged.

6. The semiconductor memory device of claim 2, further comprising:
a substrate on the second surfaces of the bit lines; and
a first sense amplifier and a second sense amplifier at least partially in the substrate,
wherein the adjacent ones of the bit lines are grouped into pairs, with the pairs alternately arranged with one another along the third direction as odd-numbered bit line pairs and even-numbered bit line pairs,
wherein the first sense amplifier and the second sense amplifier include bit line contacts electrically connecting distal ends of the adjacent ones of the bit lines included in respective ones of the pairs to each other in the first sense amplifier and the second sense amplifier,
wherein the first sense amplifier is electrically connected to the even-numbered bit line pairs, and
wherein the second sense amplifier is electrically connected to the odd-numbered bit line pairs.

7. The semiconductor memory device of claim 1, further comprising:
a capacitor structure on upper surfaces of the vertical semiconductor patterns and electrically connected to the vertical semiconductor patterns,
wherein the first ones of the vertical semiconductor patterns are shifted in the second direction relative to the second ones of the vertical semiconductor patterns.

8. The semiconductor memory device of claim 1, further comprising:
second gate structures on second side surfaces of the vertical semiconductor patterns opposite to the first side surfaces and extending in the third direction.

9. The semiconductor memory device of claim 8, wherein each of the first gate structures includes:
a first gate insulating pattern; and
a first gate electrode on a side surface of the first gate insulating pattern, and
wherein each of the second gate structures includes:
a second gate electrode extending in the third direction; and
second gate insulating patterns on opposite side surfaces of the second gate electrode and in contact with at least one of the second side surfaces of the vertical semiconductor patterns.

10. The semiconductor memory device of claim 9, wherein the first gate electrode and the second gate electrode include a metal, a conductive metal nitride, a conductive metal silicide, a conductive metal oxide, impurity-doped polysilicon, or a combination thereof.

11. The semiconductor memory device of claim 1, wherein each of the vertical semiconductor patterns includes a channel region, a first source/drain region, and a second source/drain region,
wherein the first source/drain region is at an upper end of each of the vertical semiconductor patterns,
wherein the second source/drain region is at a lower end of each of the vertical semiconductor patterns, and
wherein the channel region is between the first source/drain region and the second source/drain region.

12. A semiconductor memory device comprising:
vertical semiconductor patterns extending in a first direction;
a plurality of bit lines on lower surfaces of the vertical semiconductor patterns, each of the bit lines extending in a second direction that is perpendicular to the first direction; and
a plurality of first gate structures on first side surfaces of the vertical semiconductor patterns, each of the first gate structures extending in a third direction that is perpendicular to the first direction and intersects the second direction,
wherein the bit lines include odd-numbered bit lines and even-numbered bit lines that are alternately arranged with one another along the third direction,
wherein the first gate structures include odd-numbered first gate structures and even-numbered first gate structures that are alternately arranged with one another along the second direction,
wherein first ones of the vertical semiconductor patterns that are adjacent to the odd-numbered first gate structures are electrically connected to the odd-numbered bit lines, and
wherein second ones of the vertical semiconductor patterns that are adjacent to the even-numbered first gate structures are electrically connected to the even-numbered bit lines.

13. The semiconductor memory device of claim 12, further comprising:
a dielectric film on lower surfaces of the bit lines and between adjacent ones of the bit lines; and
a capacitor structure on upper surfaces of the vertical semiconductor patterns and electrically connected to the vertical semiconductor patterns.

14. The semiconductor memory device of claim 12, further comprising:
second gate structures on second side surfaces of the vertical semiconductor patterns opposite to the first side surfaces and extending in the third direction.

15. The semiconductor memory device of claim 14, wherein each of the first gate structures includes:
a first gate insulating pattern; and
a first gate electrode on a side surface of the first gate insulating pattern, and
wherein each of the second gate structures includes:
a second gate electrode extending in the third direction; and
second gate insulating patterns on opposite side surfaces of the second gate electrode and in contact with at least one of the second side surfaces of the vertical semiconductor patterns.

16. The semiconductor memory device of claim 12, wherein the first ones of the vertical semiconductor patterns and the second ones of the vertical semiconductor patterns are arranged in a zigzag shape along the third direction when viewed on a plane.

17. The semiconductor memory device of claim 12, further comprising:
a substrate on lower surfaces of the bit lines; and
a first sense amplifier and a second sense amplifier at least partially in the substrate,
wherein the first sense amplifier is electrically connected to the even-numbered bit lines, and
wherein the second sense amplifier is electrically connected to the odd-numbered bit lines.

18. The semiconductor memory device of claim 17, wherein, when the semiconductor memory device is operated, the first sense amplifier is configured to activate the even-numbered bit lines, and
wherein, when the even-numbered bit lines are activated, the odd-numbered bit lines are configured to be pre-charged.

19. The semiconductor memory device of claim 17, wherein, when the semiconductor memory device is operated, the second sense amplifier is configured to activate the odd-numbered bit lines, and
wherein, when the odd-numbered bit lines are activated, the even-numbered bit lines are configured to be pre-charged.

20. A semiconductor memory device comprising:
vertical semiconductor patterns extending in a first direction;
a plurality of bit lines on lower surfaces of the vertical semiconductor patterns, each of the bit lines extending in a second direction that is perpendicular to the first direction; and
a plurality of first gate structures on first side surfaces of the vertical semiconductor patterns, each of the first gate structures extending in a third direction that is perpendicular to the first direction and intersects the second direction,
wherein the bit lines include odd-numbered bit lines and even-numbered bit lines that are alternately arranged with one another along the third direction,
wherein the first gate structures include N first gate structures that are sequentially arranged along the second direction, with N being a natural number,
wherein first ones of the vertical semiconductor patterns that are adjacent to (4N-3)^{th} and (4N-2)^{th} ones of the first gate structures are electrically connected to the odd-numbered bit lines, and
wherein second ones of the vertical semiconductor patterns that are adjacent to (4N-1)^{th} and 4N^{th} ones of the first gate structures are electrically connected to the even-numbered bit lines.
